(19) United States
(12) Patent Application Publication
(10) Pub. No.: US 2015/0069410 A1
(43) Pub. Date: Mar. 12, 2015

(54) SEMICONDUCTOR DEVICE, METHOD OF MANUFACTURING THE SAME, SCHOTTKY BARRIER DIODE, AND FIELD EFFECT TRANSISTOR

(71) Applicant: FURUKAWA ELECTRIC CO., LTD., Tokyo (JP)

(72) Inventors: Kazuyuki UMENO, Tokyo (JP); Hiroshi Kambayashi, Tokyo (JP); Keishi Takaki, Tokyo (JP)

(73) Assignee: FURUKAWA ELECTRIC CO., LTD., Tokyo (JP)

(21) Appl. No.: 14/547,666

(22) Filed: Nov. 19, 2014

Related U.S. Application Data
(63) Continuation of application No. PCT/JP2013/079149, filed on Oct. 28, 2013.

(30) Foreign Application Priority Data
Oct. 26, 2012 (JP) 2012-237332

(51) Int. Cl. H01L 29/778; H01L 29/201; H01L 29/205; H01L 21/306; H01L 29/872; H01L 29/47; H01L 21/02; H01L 21/28; H01L 29/20; H01L 29/40

(52) U.S. Cl. CPC H01L 29/7787; H01L 29/2003; H01L 29/201; H01L 29/205; H01L 29/402; H01L 29/872; H01L 29/475; H01L 21/0254; H01L 21/28; H01L 21/30604
USPC 257/76; 438/454

(57) ABSTRACT

A semiconductor device includes: a base; an electron transit layer layered on the base; an electron-supplying layer being configured by layering a plurality of AlN layers and GaN layers alternately on the electron transit layer and having an average Al composition x; an etching sacrificial layer layered on the electron-supplying layer and made of Al_{y}Ga_{1-y}N (0<y<1) having an Al composition y; a field plate layer layered on the etching sacrificial layer and made of Al_{z}Ga_{1-z}N (0≦z<1, z<y) having an Al composition z; and an electrode connected to the etching sacrificial layer and being provided in an area in which a part of the field plate layer is removed until reaching the etching sacrificial layer.

### CROSS-REFERENCE TO RELATED APPLICATIONS

This application is a continuation of PCT International Application No. PCT/JP2013/079149 filed on Oct. 28, 2013 which claims the benefit of priority from Japanese Patent Application No. 2012-237332 filed on Oct. 26, 2012, the entire contents of which are incorporated herein by reference.

### BACKGROUND OF THE INVENTION

1. Field of the Invention

The present invention relates to a semiconductor device, a method of manufacturing the same, a Schottky barrier diode, and a field effect transistor.

2. Description of the Related Art

Conventionally, a configuration has been known in which an AlN/GaN-pseudo alloy is used for a barrier layer (active layer) (see Japanese Patent No. 3733420). To be more specific, Japanese Patent No. 3733420 and APPLIED PHYSICS LETTERS 90, 242112 (2007) disclose a heterojunction field-effect transistor (HFET) using a nitride semiconductor material having an effect of increasing a carrier concentration and a mobility more than a conventional AlGaN-alloy barrier layer. It is considered that, a 2-dimensional electron gas (2DEG) is produced in a pseudo-alloy layer based on a relationship between a composition and a thickness thereof, disclosed by Japanese Patent No. 3733420.

Japanese Patent No. 4592938 discloses a field plate structure made of a gallium nitride (GaN) using an AlGaN-alloy layer for an electron-supplying layer.

FIG. 4A shows a Schottky barrier diode (SBD) having a field plate structure as an example of a semiconductor device of a conventional technology. As shown in FIG. 4A, a buffer layer 102, an electron transit layer 103 made of an undoped GaN layer, and an Al_{0.25}Ga_{0.75}N layer 104 as an electron-supplying layer are formed consecutively on an Si substrate 101 of the SBD 100 configured by the conventional technology. A cathode electrode 106C as an ohmic electrode is formed selectively on the Al_{0.25}Ga_{0.75}N layer 104, and also a field plate layer (GaN-FP layer) 105 made of gallium nitride (GaN) is formed selectively on the Al_{0.25}Ga_{0.75}N layer 104. An area of the GaN-FP layer 105, in which an anode electrode is to be formed, is removed by etching until reaching the Al_{0.25}Ga_{0.75}N layer 104, and then an anode electrode 106A as a Schottky electrode is formed on the GaN-FP layer 105. An insulating film 107 is formed on the Al_{0.25}Ga_{0.75}N layer 104, the GaN-FP layer 105, the cathode electrode 106C, and the anode electrode 106A. Contact holes 107a are formed in the insulating film 107 and above the cathode electrode 106C and the anode electrode 106A respectively for contacting wirings.

### SUMMARY OF THE INVENTION

It is an object of the present invention to at least partially solve the problems in the conventional technology.

A semiconductor device according to one aspect of the present invention includes: a base; an electron transit layer layered on the base; an electron-supplying layer configured by layering a plurality of AlN layers and GaN layers alternately on the electron transit layer, the electron-supplying layer having an average Al composition x; an etching sacrificial layer layered on the electron-supplying layer and made of Al_{y}Ga_{1-y}N (0<y<1) having an Al composition y; a field plate layer layered on the etching sacrificial layer and made of Al_{z}Ga_{1-z}N (0≦z<1, z<y) having an Al composition z; and an electrode connected to the etching sacrificial layer and being provided in an area in which a part of the field plate layer is removed until reaching the etching sacrificial layer.

A Schottky barrier diode according to another aspect of the present invention includes: a base; an electron transit layer layered on the base; an electron-supplying layer configured by layering each of a plurality of AlN layers and each of a plurality of GaN layers alternately on the electron transit layer, the electron-supplying layer having an average Al composition x; an etching sacrificial layer layered on the electron-supplying layer and made of Al_{y}Ga_{1-y}N (0<y<1) having an Al composition y; a field plate layer layered on the etching sacrificial layer and made of (0≦z<1, z<y) having an Al composition z; an electrode which is an anode electrode connected to the etching sacrificial layer and being provided in an area in which a part of the field plate layer is removed until reaching the etching sacrificial layer; and a cathode electrode connected to the etching sacrificial layer.

A heterojunction field-effect transistor according to still another aspect of the present invention includes: a base; an electron transit layer layered on the base; an electron-supplying layer configured by layering each of a plurality of AlN layers and each of a plurality of GaN layers alternately on the electron transit layer, the electron-supplying layer having an average Al composition x; an etching sacrificial layer layered on the electron-supplying layer and made of Al_{y}Ga_{1-y}N (0<y<1) having an Al composition y; a field plate layer layered on the etching sacrificial layer and made of Al_{z}Ga_{1-z}N (0≦z<1, z<y) having an Al composition z; an electrode which is a gate electrode connected to the etching sacrificial layer and being provided in an area in which a part of the field plate layer is removed until reaching the etching sacrificial layer; and a source electrode and a drain electrode connected to the etching sacrificial layer.

A MIS field effect transistor according to still another aspect of the present invention includes: a base; an electron transit layer layered on the base; an electron-supplying layer configured by layering each of a plurality of AlN layers and each of a plurality of GaN layers alternately on the electron transit layer, the electron-supplying layer having an average Al composition x; an etching sacrificial layer layered on the electron-supplying layer and made of Al_{y}Ga_{1-y}N (0<y<1) having an Al composition y; a field plate layer layered on the etching sacrificial layer and made of Al_{z}Ga_{1-z}N (0≦z<1, z<y) having an Al composition z; an electrode which is a gate electrode connected to the etching sacrificial layer via a gate insulating film, and being provided in an area in which a part of the field plate layer is removed until reaching the etching sacrificial layer; and

a source electrode and a drain electrode connected to the etching sacrificial layer.

A method of manufacturing a semiconductor device according to still another aspect of the present invention, the semiconductor device includes: a base; an electron transit layer layered on the base; an electron-supplying layer configured by layering each of a plurality of AlN layers and each of a plurality of GaN layers alternately on the electron transit layer, the electron-supplying layer having an average Al composition x; an etching sacrificial layer layered on the electron-supplying layer and made of Al_{y}Ga_{1-y}N (0<y<1) having an Al composition y; a field plate layer layered on the etching sacrificial layer and made of Al_{z}Ga_{1-z}N (0≦z<1) having an Al composition z; and an electrode provided in an area in which a part of the field plate layer is removed until reaching the etching sacrificial layer, the average Al composition x of the electron-supplying layer, the Al composition y of the etching sacrificial layer, and the Al composition z of the field plate layer satisfy a relationship of x≧y>z, and etching at least an area in which the electrode is formed in the field plate layer by dry etching using a chlorine-based gas.

The above and other features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross-sectional view showing a layered structure of an electron-supplying layer, an etching sacrificial layer, and a field plate layer according to an embodiment of the present invention;

FIG. 2 is a graph showing dependencies of carrier densities, per Al compositions, of 2-dimensional electron gas in an etching sacrificial layer made of an Al_{y}Ga_{1-y}N layer;

FIG. 3A is a cross-sectional view showing an SBD structure having a field plate structure in which an etching sacrificial layer is provided on the electron-supplying layer according to a first embodiment;

FIG. 3B is a cross-sectional view showing an HEMT structure having a field plate structure in which an etching sacrificial layer is provided on the electron-supplying layer according to a second example embodiment;

FIG. 4A is a cross-sectional view showing a basic structure of an SBD as an example of a semiconductor device having a field plate structure according to a conventional technology;

FIG. 4B is a cross-sectional view showing a layered structure of a semiconductor device according to the conventional technology shown in FIG. 4A; and

FIG. 4C is a cross-sectional view showing a structure of an electron-supplying layer in detail contrived by the present inventors.

### DETAILED DESCRIPTION OF THE PREFERRED EMBODIMENTS

Hereinafter, embodiments of a semiconductor device according to the present invention will be described in detail with reference to the drawings. However, the present invention is not limited to these embodiments. Also, in each drawing, if deemed appropriate, identical or equivalent elements are given same reference numerals. In addition, the drawings are schematic depictions, and do not represent the actual relation of dimension of each element. Furthermore, different drawings may include portions using different scales and dimensional relations.

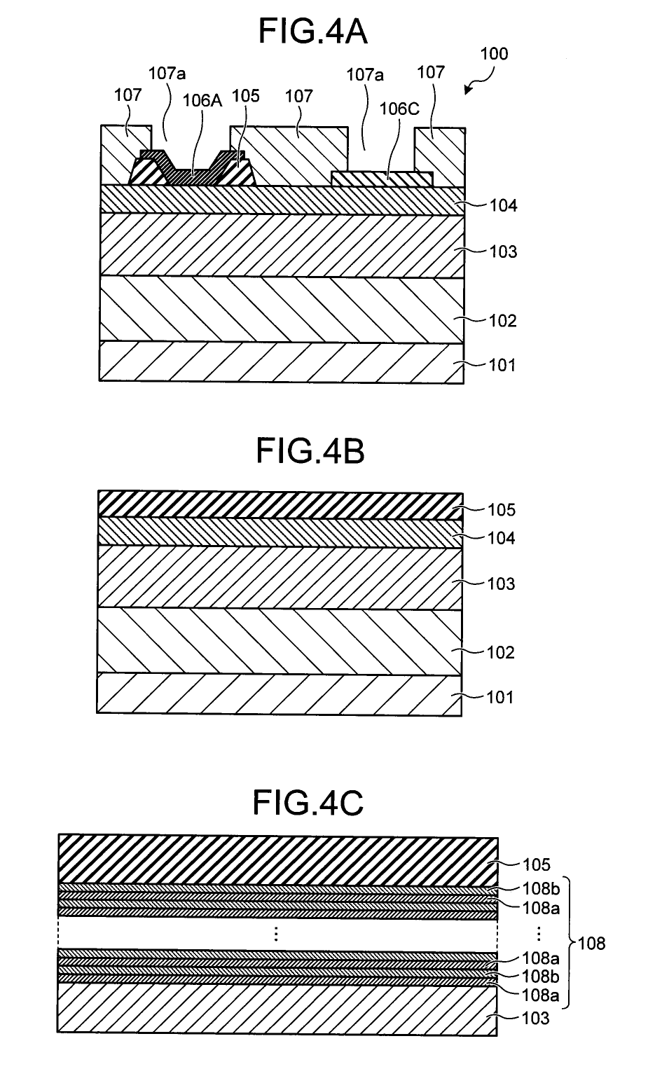

Present inventors contrived to adapt a pseudo alloy multi-layer structure of an AlN barrier layer/GaN quantum level layer as a barrier layer for reducing a sheet resistance and a contact resistance of an ohmic electrode which are problematic characteristics of a conventional semiconductor device. FIGS. 4B and 4C are cross-sectional views showing respectively a layered structure of the conventional semiconductor device and a layered structure of a semiconductor device contrived by the present inventors.

That is, the present inventors contrived a configuration of, in place of forming an electron-supplying layer in a semiconductor device such as an SBD 100 shown in FIG. 4B by the Al_{0.25}Ga_{0.75}N layer 104, realizing a so-called pseudo alloy structure of an AlN/GaN superlattice layer 108 in which each of aluminum nitride (AlN) layers 108a and each of gallium nitride (GaN) layers 108b are layered alternately and consecutively as shown in FIG. 4C. Since this configuration increases an average Al composition of the pseudo alloy and a thickness of the electron-supplying layer easily without causing a lattice relaxation, an effect which is capable of increasing a carrier density of 2 Dimensional Electron Gas easily is obtained. Furthermore, since a conduction band edge of the electron-supplying layer is raised by a quantum effect higher than that of the AlGaN-alloy having a same Al composition, an effect capable of increasing a mobility is obtained since the conduction band edge leans to one side in a base's direction to decrease a scattering factor.

To be more specific, in a case of the conventional structure as shown in FIGS. 4A and 4B in which a GaN field plate layer (GaN-FP layer) 105 is provided furthermore on the Al_{0.25}Ga_{0.75}N layer 104 for restraining a Schottky leakage in the semiconductor device, a carrier density of the 2-dimensional electron gas was 8×10¹² cm⁻². By contrast, in a case contrived by the present inventors where the electron-supplying layer is an AlN/GaN superlattice layer 108 of the pseudo alloy structure and the GaN-FP layer 105 for restraining the Schottky leakage is provided on the AlN/GaN superlattice layer 108, it was possible to obtain a carrier density of 1.3×10¹³ cm⁻² for the 2-dimensional electron gas and increase the carrier density of the 2-dimensional electron gas by approximately 1.5 times more than that of the conventional structure.

However, a verification of a production of the semiconductor device conducted by the present inventors proved that removing the GaN-FP layer 105 shown in FIG. 4C selectively by etching using a chlorine-based gas until reaching an upper surface of the electron-supplying layer inevitably caused the GaN layer 108b that is the upmost layer of the AlN/GaN superlattice layer 108 to be etched to expose the AlN layer 108a as an upmost surface.

A knowledge of the present inventors indicates that an etching rate of GaN is greater than an etching rate of AlN to an extremely great extent. Therefore, it was difficult to precisely control and stop etching of the GaN-FP layer 105 or the GaN layer 108b to leave the GaN layer 108b. For that reason, there was a problem that a surface oxidation or the like of the AlN layer 108a caused an increase in an ON voltage or a contact resistance, or that a current collapse worsened.

In contrast, according to the embodiment described below, it is possible to provide an advantage that a semiconductor device, a method of manufacturing the same, a Schottky barrier diode, and a field effect transistor that is capable of controlling etching of a layer formed above an electron-supplying layer without worsening characteristics of a semiconductor device in a case where the electron-supplying layer has a pseudo alloy structure which is a superlattice layer in which at least two kinds of bimaterials are layered alternately.

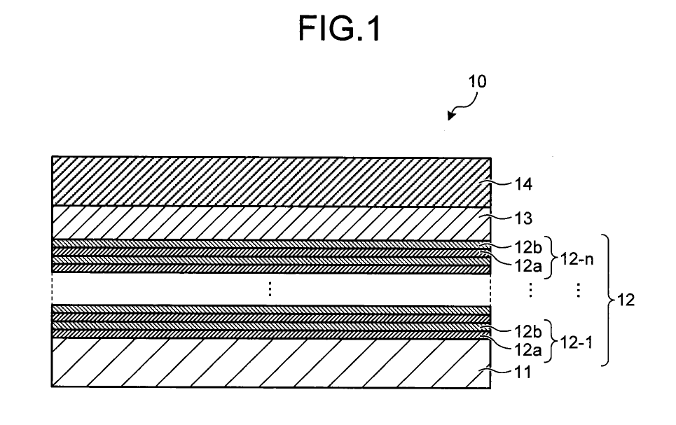

FIG. 1 is a cross-sectional view showing a layered structure in the vicinity of an electron-supplying layer in a semiconductor device according to an embodiment of the present invention. That is, an electron-supplying layer 12 of a pseudo alloy structure made of AlN/GaN layers 12-1 to 12-n (n: natural number) in which each of a plurality of AlN layers 12a and each of a plurality of GaN layers 12b are layered alternately and consecutively is provided on or above an electron transit layer 11 made of, for example, an undoped GaN layer formed on a predetermined base (not shown in FIG. 1) in a semiconductor device 10 according to the present embodiment.

Herein the electron-supplying layer 12 has an AlGaN pseudo alloy structure made of an AlN/GaN superlattice layer constituted by the respective AlN/GaN layers 12-1 to 12-n constituting the electron-supplying layer 12 according to the present embodiment. The AlN layers 12a and the GaN layers 12b are formed respectively in thicknesses to a degree that at least a 2-dimensional electron gas is not produced therein.

An average Al composition x for the electron-supplying layer 12 made of the AlN/GaN layers 12-1 to 12-n is calculated by Equation (1) where x indicates an average Al composition, xi indicates an average Al composition for the AlN/GaN layer 12-i (i:1, 2, . . . , n) and di indicates a thickness of the AlN/GaN layer 12-i.

$$x = \frac{{\sum }_{i = 1}^{n} xi \cdot di}{{\sum }_{i = 1}^{n} di} \qquad ( 1 )$$

In the present embodiment, the average Al composition x for the electron-supplying layer 12 is presupposed to be 0<x≦1, and when considering that a sheet resistance should be lowered, it is preferable that the average Al composition x is approximately an intermediate value between that in a case of a single layer of AlGaN and that in a case of AlN/GaN, i.e., equal to or greater than 10% and equal to or less than 70% (0.1≦x≦0.7). From a view point of a sheet resistance in a case of using a pseudo alloy barrier layer, it is more preferable that the average Al composition x for the electron-supplying layer 12 is equal to or greater than 20% and equal to or less than 50% (0.2≦x≦0.5) estimated for the superlattice barrier layer. Moreover, from a view point of a lattice relaxation capable of layering freely from a deformation, it is preferable that the average Al composition x for the electron-supplying layer 12 is equal to or greater than 20% and equal to or less than 35% (0.2≦x≦0.35).

Moreover, when considering an attempt of increasing the carrier density of the 2-dimensional electron gas (2DEG), it is preferable that the thickness of the electron-supplying layer 12 which is equivalent to a denominator in Equation (1) is equal to or greater than 10 nm to be equal to or less than a critical thickness at which a misfit dislocation does not occur. When considering the limit of an ohmic contact, it is preferable that the thickness of the electron-supplying layer 12 is equal to or less than 100 nm.

It is preferable that the thicknesses of the AlN layers 12a and the GaN layers 12b constituting the electron-supplying layer 12 respectively are equal to or greater than two atomic layers that is a minimum thickness of forming layered layers, to be more specific, for example, equal to or greater than 0.5 nm. In order to prevent a misfit dislocation, it is preferable that the thicknesses of the respective AlN layers 12a and GaN layers 12b are equal to or less than a critical thickness. Optimum values of the average Al composition x and the thickness di for each of the AlN/GaN layers 12-1 to 12-n are calculated appropriately based on the conditions described above and in accordance with a design of the semiconductor device.

The electron-supplying layer 12 may be configured so that a ratio of thicknesses of the layered AlN layers 12a and the layered GaN layers 12b are equal to each other or so that the thicknesses of the layered AlN layers 12a are equal and the thicknesses of the layered GaN layers 12b are equal. That is, an average Al composition x can be calculated from Equation (2) below in a case where a plurality of AlN/GaN layers 12-i constitute the electron-supplying layer 12 so that the average Al composition xi remains unchanged along a direction in which the AlN/GaN layers 12-i are layered. In a pair of the AlN/GaN layer, d1 indicates the thickness of the AlN layer 12a and d2 indicates the thickness of the GaN layer 12b.

$$x = \frac{d 1}{d 1 + d 2} \qquad ( 2 )$$

The electron-supplying layer 12 having such average Al composition x becomes the AlN/GaN superlattice layer in which an AlN layer and a GaN layer are configured to be layered alternately as a pair.

Provided consecutively on the electron-supplying layer 12 configured as described above are an etching sacrificial layer 13 made of an Al_{y}Ga_{1-y}N layer (0<y<1) of which Al composition y is equal to or lower than an average Al composition x (y≦x) and a field plate layer (FP layer) 14 made of an Al_{z}Ga_{1-z}N layer (0≦z<1) of which Al composition z is lower than Al composition y (z<y).

That is, the semiconductor device 10 according to the present embodiment is configured so that the average Al composition x of the electron-supplying layer 12, the Al composition y of the etching sacrificial layer 13, and the Al composition z of the FP layer 14 satisfy a relationship of z<y≦x. Since it is configured so that the Al compositions are made smaller in upper layers, a carrier density of the 2-dimensional electron gas produced from the electron-supplying layer 12 is not affected to a great extent. Furthermore, since a lattice relaxation is not caused, for example, it is possible to make an etching rate for the FP layer 14 different from an etching rate for the etching sacrificial layer 13 to a great extent in a case of etching the FP layer 14 by a dry etching method using a chlorine-based gas, it is possible to control the etching for the FP layer 14 efficiently. When considering an effective etching of the FP layer 14 and maintaining the characteristics of the semiconductor device to maintain a withstand voltage at an end portion of the FP layer 14 and not to decrease the carrier density of the 2-dimensional electron gas to a great extent, it is preferable that the thickness of the FP layer 14 is equal to or greater than 10 nm and equal to or less than 200 nm (10 to 200 nm) to select a preferable thickness from this thickness range in accordance with a designed condition for the semiconductor device.

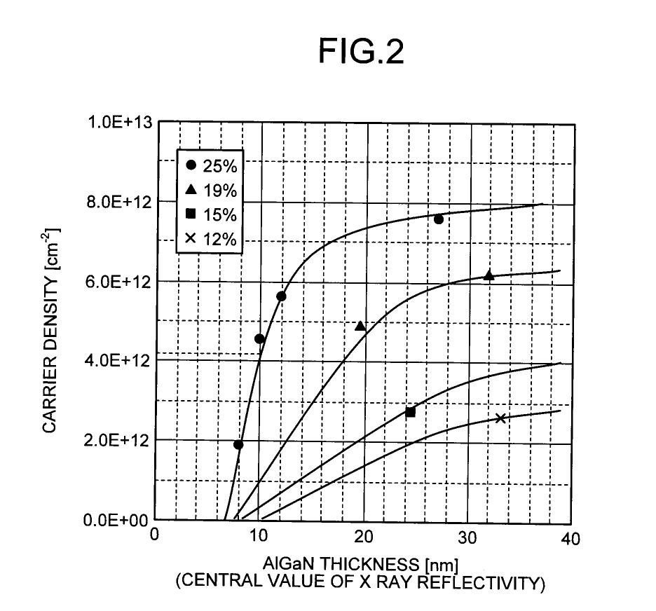

The present inventors measured the carrier density of the 2-dimensional electron gas with respect to its dependency on the thickness of the etching sacrificial layer 13 for restraining the 2-dimensional electron gas as much as possible from being produced at an interface between the etching sacrificial layer 13 and the electron-supplying layer 12. In this measurement, the Al composition y of the etching sacrificial layer 13 was changed variously. FIG. 2 is a graph showing the result of the measurement.

FIG. 2 indicates that the thickness of the etching sacrificial layer 13 made of an Al_{y}Ga_{1-y}N layer is equal to or smaller than 10 nm in order to make the carrier density of the 2-dimensional electron gas equal to or less than 4×10¹² cm⁻² at which the 2-dimensional electron gas being produced and affecting the semiconductor device is ignorable, even in a case where the Al composition y of the etching sacrificial layer 13 is considered to be 25% (y=0.25). Therefore, in order to make the 2-dimensional electron gas produced at the etching sacrificial layer 13 reduced to an ignorable degree in the present embodiment, it is preferable to make its thickness equal to or smaller than 10 nm.

In consideration of a precise control of etching the FP layer 14 using the Al_{y}Ga_{1-y}N layer layered on the electron-supplying layer 12, it is preferable to make the thickness of the etching sacrificial layer 13 equal to or larger than 1 nm. This is because, in a case where the FP layer 14 provided on the Al_{y}Ga_{1-y}N layer is, for example, a GaN layer or the like of which Al composition z is zero or extremely low, an etching rate of the GaN layer is extremely large, i.e., approximately 100 times an etching rate of an AlGaN layer, and thus the AlGaN layer serves as the etching sacrificial layer 13 for the GaN layer constituting the FP layer 14 extremely effectively.

In the semiconductor device having the layered structure according to the embodiment configured as above, it is possible to restrain an increase in a leakage current caused by the 2-dimensional electron gas produced at an interface between the etching sacrificial layer 13 and the upmost layer of the electron-supplying layer 12, i.e., the upmost GaN layers 12b. It is hereby possible to prevent the characteristics of the semiconductor device from worsening.

An embodiment of the semiconductor device having the electron-supplying layer 12, the etching sacrificial layer 13, and the FP layer 14 according to the embodiment of the present invention configured as above will be explained next.

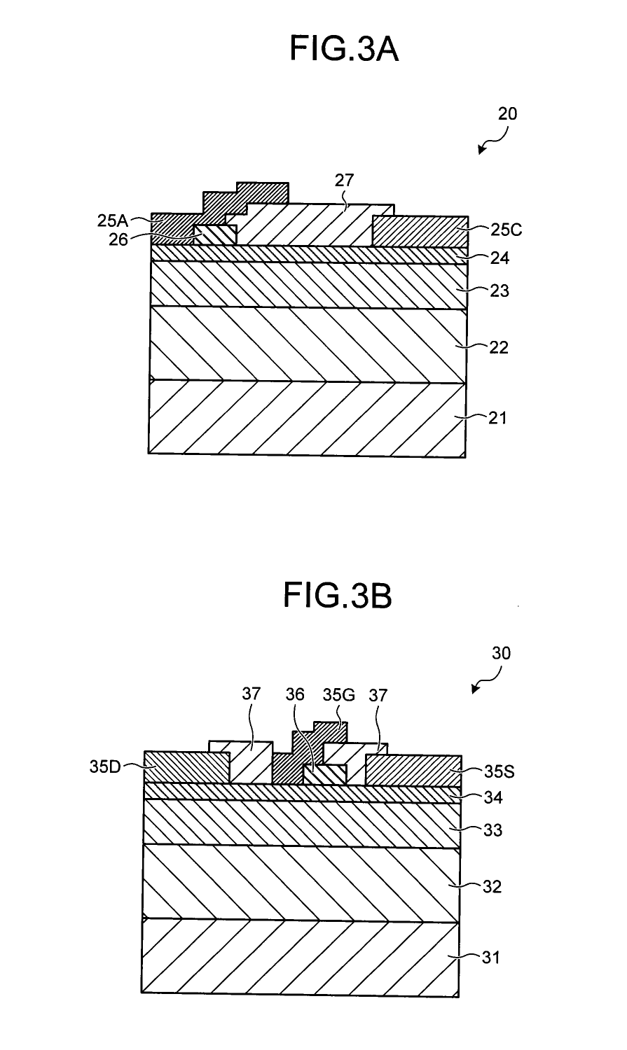

FIG. 3A is a cross-sectional view showing an example of a Schottky barrier diode (SBD) provided with the FP layer according to the first embodiment. As shown in FIG. 3A, the SBD 20 according to the first embodiment is formed by layering a base 21, an electron transit layer 22, an electron-supplying layer 23, and an etching sacrificial layer 24 consecutively.

The base 21 is configured by providing various layers, such as, for example, a buffer layer made of a GaN layer, an AlN layer or the like which are necessary for constituting the semiconductor device, on a substrate, such as, for example, a silicon (Si) substrate, a gallium arsenide (GaAs) substrate, a gallium phosphide (GaP) substrate, a GaN substrate, an AlN substrate, a silicon carbide (SiC) substrate, a carbon (C) substrate, or a sapphire substrate. The electron transit layer 22, the electron-supplying layer 23, and the etching sacrificial layer 24 have configurations that are similar to those of the electron transit layer 11, the electron-supplying layer 12, and the etching sacrificial layer 13 respectively according to the above-described embodiment.

In the SBD 20, a cathode electrode 25C as an ohmic electrode is provided on the etching sacrificial layer 24 selectively. Provided on the etching sacrificial layer 24 is a GaN-FP layer 26 made of a GaN layer of which Al composition z is zero. An unnecessary portion including an area for forming an anode electrode is removed by etching selectively from the GaN layer. The GaN-FP layer 26 has a configuration similar to that of the FP layer 14 according to the above-described embodiment. The unnecessary portion of the GaN layer is removed by etching selectively by a dry etching method using, for example, a chlorine-based gas.

Provided on the etching sacrificial layer 24 is an insulating film 27 covering a part of the cathode electrode 25C and a part of the GaN-FP layer 26. Provided furthermore is an anode electrode 25A as a Schottky electrode having a field plate structure overriding the GaN-FP layer 26 and the insulating film 27 and being connected to the etching sacrificial layer 24. The anode electrode 25A is made of, for example, a Ni/Au layer in which a Nickel (Ni) and an aurum (Au) are layered consecutively. The SBD 20 according to the first embodiment is configured as described above.

FIG. 3B is a cross-sectional view showing an example of an HEMT provided with a GaN-FP layer according to a second embodiment. As shown in FIG. 3B, similarly to the first embodiment, an electron transit layer 32, an electron-supplying layer 33, and an etching sacrificial layer 34 are layered consecutively on a base 31 in the HEMT 30 according to the second embodiment. The base 31 has a configuration similar to that of the base 21. A conventionally known substrate and various layers, that are necessary for configuring the HEMT 30, are provided to the base 31. The electron transit layer 32, the electron-supplying layer 33, and the etching sacrificial layer 34 have configurations that are similar to those of the electron transit layer 11, the electron-supplying layer 12, and the etching sacrificial layer 13 respectively according to the above-described embodiment.

A source electrode 35S and a drain electrode 35D are provided on the etching sacrificial layer 34 selectively. The source electrode 35S and the drain electrode 35D serve as ohmic electrodes formed on the etching sacrificial layer 34. Provided between the source electrode 35S and the drain electrode 35D is a GaN-FP layer 36 made of a GaN layer of which Al composition z is zero. An unnecessary portion including an area for forming a gate electrode is removed selectively from the GaN layer by etching. The GaN-FP layer 36 has a configuration similar to that of the FP layer 14 according to the embodiment described above. The unnecessary portion of the GaN layer is removed selectively by etching, e.g. a dry etching method using, for example, a chlorine-based gas.

Provided on the etching sacrificial layer 34 is an insulating film 37 covering a part of the source electrode 35S, a part of the drain electrode 35D, and a part of the GaN-FP layer 36. Provided between the source electrode 35S and the drain electrode 35D is a gate electrode 35G as a Schottky electrode made of, for example, a Ni/Au layer connected to the etching sacrificial layer 34. The gate electrode 35G has a field plate structure of, while being connected to the etching sacrificial layer 34, overriding the GaN-FP layer 36 and the insulating film 37. The HEMT 30 according to the second embodiment is configured as described above. A field effect transistor may be configured so that a gate insulating film and a gate electrode 35G are provided on the etching sacrificial layer 34 as a metal insulator semiconductor (MIS) gate.

According to the above-described embodiments of the present invention, in a case where an electron-supplying layer of a semiconductor device is of a pseudo alloy structure in which an AlN layer and a GaN layer are layered alternately, it is possible to control an etching of a layer formed above the electron-supplying layer without worsening characteristics of the semiconductor device by providing an etching sacrificial layer made of an AlGaN layer containing Al on the layered on the pseudo alloy structure. Moreover, since it is possible to prevent an AlN layer constituting an electron-supplying layer, when being etched, from being exposed on the upmost surface by providing an etching sacrificial layer on the electron-supplying layer configured by an AlN/GaN superlattice layer, it is possible to prevent an ON voltage or a contact resistance from increasing or to prevent a current collapse from worsening by a surface oxidation or the like.

The embodiments of the present invention are explained above specifically, and the present invention is not limited to the above-described embodiments, and various modifications are possible based on a technical idea of the present invention. For example, numerical values specified in the above-described embodiments are mere examples, a numerical values which is other than the above-described numerical values may be used if necessary. The present invention is not limited by the above-described embodiments. The present invention also includes a configuration combining the above-described elements appropriately. Further effects or modifications can be derived by those skilled in the art easily.

In the first and second embodiments described above, various pseudo alloy structures that are other than the electron-supplying layer described above can be adapted corresponding to a structural design based on a desirable characteristics of a semiconductor device.

A configuration can be adapted in which a spacer layer made of an AlN layer is disposed between the electron transit layer 22 and the electron-supplying layer 23 according to the above-described first embodiment and between the electron transit layer 32 and the electron-supplying layer 33 according to the above-described second embodiment.

According to the semiconductor device, the method of manufacturing the same, the Schottky barrier diode, and the field effect transistor according to the present invention, in a case where the electron-supplying layer has a pseudo alloy structure which is a superlattice layer in which at least two kinds of materials are layered alternately, it is possible to control etching of a layer formed above an electron-supplying layer without worsening characteristics of the semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a base;
an electron transit layer layered on the base;
an electron-supplying layer configured by layering each of a plurality of AlN layers and each of a plurality of GaN layers alternately on the electron transit layer, the electron-supplying layer having an average Al composition x;
an etching sacrificial layer layered on the electron-supplying layer and made of Al_{y}Ga_{1-y}N (0<y<1) having an Al composition y;
a field plate layer layered on the etching sacrificial layer and made of Al_{z}Ga_{1-z}N (0≦z<1, z<y) having an Al composition z; and
an electrode connected to the etching sacrificial layer and being provided in an area in which a part of the field plate layer is removed until reaching the etching sacrificial layer.

2. The semiconductor device according to claim 1, wherein the average Al composition x of the electron-supplying layer, the Al composition y of the etching sacrificial layer, and the Al composition z of the field plate layer satisfy a relationship of x≦y>z.

3. The semiconductor device according to claim 1, wherein the etching sacrificial layer is formed in a thickness which prevents a 2-dimensional electron gas from being produced between the electron-supplying layer and the etching sacrificial layer.

4. The semiconductor device according to claim 3, wherein the thickness of the etching sacrificial layer is equal to or greater than 1 nm and equal to or less than 10 nm.

5. The semiconductor device according to claim 1, wherein the AlN layers and the GaN layers in a pseudo alloy constituting the electron-supplying layer are in thicknesses preventing a 2-dimensional electron gas from being produced at any one of the AlN layers and at any one of the GaN layers in the electron-supplying layer.

6. The semiconductor device according to claim 1, wherein a thickness of the electron-supplying layer is equal to or greater than 10 nm and equal to or less than 100 nm.

7. The semiconductor device according to claim 1, wherein an average Al composition in the electron-supplying layer is equal to or greater than 10% and equal to or less than 70%.

8. The semiconductor device according to claim 1, wherein an average Al composition in the electron-supplying layer is equal to or greater than 20% and equal to or less than 50%.

9. The semiconductor device according to claim 1, wherein an average Al composition in the electron-supplying layer is equal to or greater than 20% and equal to or less than 35%.

10. The semiconductor device according to claim 1, wherein a thickness of the field plate layer is equal to or greater than 10 nm and equal to or less than 200 nm.

11. A Schottky barrier diode comprising:
a base;
an electron transit layer layered on the base;
an electron-supplying layer configured by layering each of a plurality of AlN layers and each of a plurality of GaN layers alternately on the electron transit layer, the electron-supplying layer having an average Al composition x;
an etching sacrificial layer layered on the electron-supplying layer and made of Al_{y}Ga_{1-y}N (0<y<1) having an Al composition y;
a field plate layer layered on the etching sacrificial layer and made of Al_{z}Ga_{1-z}N (0≦z<1, z<y) having an Al composition z;
an electrode which is an anode electrode connected to the etching sacrificial layer and being provided in an area in which a part of the field plate layer is removed until reaching the etching sacrificial layer; and
a cathode electrode connected to the etching sacrificial layer.

12. The Schottky barrier diode according to claim 11, wherein the electrode is made of a Ni/Au layer in which a Nickel and an aurum are layered.

13. A heterojunction field-effect transistor comprising:
a base;
an electron transit layer layered on the base;
an electron-supplying layer configured by layering each of a plurality of AlN layers and each of a plurality of GaN layers alternately on the electron transit layer, the electron-supplying layer having an average Al composition x;
an etching sacrificial layer layered on the electron-supplying layer and made of Al_{y}Ga_{1-y}N (0<y<1) having an Al composition y;
a field plate layer layered on the etching sacrificial layer and made of Al_{z}Ga_{1-z}N (0≦z<1, z<y) having an Al composition z;
an electrode which is a gate electrode connected to the etching sacrificial layer and being provided in an area in which a part of the field plate layer is removed until reaching the etching sacrificial layer; and
a source electrode and a drain electrode connected to the etching sacrificial layer.

14. An MIS field effect transistor comprising:
a base;
an electron transit layer layered on the base;
an electron-supplying layer configured by layering each of a plurality of AlN layers and each of a plurality of GaN layers alternately on the electron transit layer, the electron-supplying layer having an average Al composition x;
an etching sacrificial layer layered on the electron-supplying layer and made of Al_{y}Ga_{1-y}N (0<y<1) having an Al composition y;
a field plate layer layered on the etching sacrificial layer and made of Al_{z}Ga_{1-z}N (0≦z<1, z<y) having an Al composition z;
an electrode which is a gate electrode connected to the etching sacrificial layer via a gate insulating film and being provided in an area in which a part of the field plate layer is removed until reaching the etching sacrificial layer; and
a source electrode and a drain electrode connected to the etching sacrificial layer.

15. A method of manufacturing a semiconductor device, the semiconductor device including: a base; an electron transit layer layered on the base; an electron-supplying layer configured by layering each of a plurality of AlN layers and each of a plurality of GaN layers alternately on the electron transit layer, the electron-supplying layer having an average Al composition x; an etching sacrificial layer layered on the electron-supplying layer and made of Al_{y}Ga_{1-y}N (0<y<1) having an Al composition y; a field plate layer layered on the etching sacrificial layer and made of Al_{z}Ga_{1-z}N (0≦z<1) having an Al composition z; and an electrode provided in an area in which a part of the field plate layer is removed until reaching the etching sacrificial layer, wherein
the average Al composition x of the electron-supplying layer, the Al composition y of the etching sacrificial layer, and the Al composition z of the field plate layer satisfy a relationship of x≦y>z, and
etching at least an area in which the electrode is formed in the field plate layer by dry etching using a chlorine-based gas.
